(19) United States
(12) Patent Application Publication
(10) Pub. No.: US 2023/0389179 A1
(43) Pub. Date: Nov. 30, 2023

(54) METHOD FOR PRODUCING WIRING CIRCUIT BOARD

(71) Applicant: NITTO DENKO CORPORATION, Osaka (JP)

(72) Inventors: Kazutoshi KINOSHITA, Osaka (JP); Hayato TAKAKURA, Osaka (JP); Ryosuke SASAOKA, Osaka (JP)

(73) Assignee: NITTO DENKO CORPORATION, Osaka (JP)

(21) Appl. No.: 18/323,131

(22) Filed: May 24, 2023

(30) Foreign Application Priority Data
May 31, 2022 (JP) 2022-089179

(51) Int. Cl. H05K 1/14; H05K 1/03; H05K 1/05; H05K 3/00

(52) U.S. Cl. CPC H05K 1/14; H05K 1/0306; H05K 1/05; H05K 3/0044; H05K 2203/0228

(57) ABSTRACT

Provided is a method for producing a wiring circuit board having excellent transportability. The method for producing a wiring circuit board includes a first step to a third step. In the first step, an assembly sheet is overlapped with a supporting sheet in a thickness direction. The assembly sheet includes a plurality of wiring circuit boards and a supporting portion supporting the plurality of wiring circuit boards. The supporting portion supports the assembly sheet. In the second step, the plurality of wiring circuit boards are separated from the supporting portion by cutting. In the third step, the assembly sheet including the plurality of wiring circuit boards separated from the supporting portion is conveyed, while being supported by the supporting sheet.

### CROSS-REFERENCE TO RELATED APPLICATION

The present application claims priority from Japanese Patent Application No. 2022-089179 filed on May 31, 2022, the contents of which are hereby incorporated by reference into this application.

### TECHNICAL FIELD

The present invention relates to a method for producing a wiring circuit board.

### BACKGROUND ART

A method is known in which in an assembly sheet including a plurality of wiring circuit boards and a supporting portion supporting the plurality of wiring circuit boards, the plurality of wiring circuit boards are separated from the supporting portion by cutting (ref: for example, Patent Document 1 below).

### CITATION LIST

### Patent Document

Patent Document 1: Japanese Unexamined Patent Publication No. 2020-27880

### SUMMARY OF THE INVENTION

### Problem to be Solved by the Invention

In the method described in Patent Document 1, since the separated plurality of wiring circuit boards after cutting are conveyed one by one, there is a problem that the process is complicated and the transportability is low.

The present invention provides a method for producing a wiring circuit board having excellent transportability.

### Means for Solving the Problem

The present invention (1) includes a method for producing a wiring circuit board including a first step of overlapping an assembly sheet including a plurality of wiring circuit boards and a supporting portion supporting the plurality of wiring circuit boards, and a supporting sheet for supporting the assembly sheet, in a thickness direction; after the first step, a second step of separating the plurality of wiring circuit boards from the supporting portion by cutting; and after the second step, a third step of conveying the assembly sheet including the plurality of wiring circuit boards separated from the supporting portion, while being supported by the supporting sheet.

According to this producing method, since the plurality of wiring circuit boards which are separated from the supporting portion are conveyed, while being supported by the supporting sheet, the transportability of the plurality of wiring circuit boards is excellent.

The present invention (2) includes the method for producing a wiring circuit board described in (1), wherein the supporting sheet has an opening portion penetrating the thickness direction; the assembly sheet includes a joint connecting the plurality of wiring circuit boards to the supporting portion; in the first step, the assembly sheet is overlapped with the supporting sheet so that the opening portion includes the joint when viewed in the thickness direction; and in the second step, the joint is cut.

According to this producing method, since in the second step, the joint is cut, it is possible to reliably and easily separate the wiring circuit board from the supporting portion.

Furthermore, since in the first step, the assembly sheet is overlapped with the supporting sheet so that the opening portion includes the joint when viewed in the thickness direction, in the second step, it is possible to suppress the contact of a cutting tool with the supporting sheet, and furthermore, to suppress the damage of the supporting sheet. Therefore, it is possible to suppress the occurrence of a foreign matter (dust generation) due to the above-described contact.

Further, since the damage of the supporting sheet is suppressed, after the third step, it is possible to reuse the supporting sheet.

The present invention (3) includes the method for producing a wiring circuit board described in (1) or (2), wherein the supporting sheet is a resin sheet.

According to this producing method, since the supporting sheet is the resin sheet, the handling of the supporting sheet is simple, and the transportability of the plurality of wiring circuit boards using the supporting sheet is further more excellent.

The present invention (4) includes the method for producing a wiring circuit board described in any one of (1) to (3), wherein both the wiring circuit board and the supporting portion include a metal supporting layer, an insulating layer, and a wiring layer in order toward one side in the thickness direction.

The present invention (5) includes the method for producing a wiring circuit board described in any one of (1) to (4), wherein a thickness of the assembly sheet is 500 μm or less.

The present invention (6) includes the method for producing a wiring circuit board described in any one of (2) to (5), wherein the plurality of opening portions are disposed at intervals, and a total opening ratio of the plurality of opening portions in the supporting sheet is 20% or more.

According to this producing method, since the total opening ratio of the plurality of opening portions is 20% or more, in the second step, it is possible to suppress the deformation of a portion facing the opening portion in the assembly sheet.

The present invention (7) includes the method for producing a wiring circuit board described in any one of (2) to (6), wherein a thickness of the supporting sheet is 150 μm or less.

According to this producing method, in the second step, it is possible to suppress the deformation of the portion facing the opening portion in the assembly sheet.

The present invention (8) includes the method for producing a wiring circuit board described in (6) or (7), wherein in the first step, the assembly sheet and the supporting sheet are disposed between a first mold having a punch, and a second mold disposed at intervals from the first mold in the thickness direction and having a hole so that the assembly sheet faces the first mold and the supporting sheet faces the second mold, and in the second step, the joint is punched by inserting the punch into the hole.

In the first step, when the assembly sheet and the supporting sheet are disposed between the first mold and the second mold so that the assembly sheet faces the first mold having the punch and the supporting sheet faces the second mold having the hole, in the second step, it is possible to improve the position accuracy at the time of punching.

On the other hand, in the second step, when the punch is inserted into the hole, in the assembly sheet, a portion in the outer vicinity of the punch and facing the opening portion is moved toward the opening portion. Then, the assembly sheet may be deformed due to the movement of the above-described portion of the assembly sheet.

However, since this producing method has a configuration of the above-described (6) or (7), it is possible to effectively suppress the above-described deformation.

### Effect of the Invention

The present invention provides a method for producing a wiring circuit board having excellent transportability.

### BRIEF DESCRIPTION OF THE DRAWINGS

FIGS. 1A to 1D show steps for illustrating one embodiment of a method for producing a wiring circuit board of the present invention:

FIG. 1A illustrating a step of preparing an assembly sheet, a first mold, and a second mold,

FIG. 1B illustrating a first step, and a cross-sectional view along an X-X line of FIG. 2A,

FIG. 1C illustrating a second step, and a cross-sectional view along a Y-Y line of FIG. 2B, and

FIG. 1D illustrating a third step.

FIGS. 2A to 2B show plan views of one embodiment:

FIG. 2A illustrating a first step and

FIG. 2B illustrating a second step.

FIGS. 3A to 3B show plan views of members prepared in the first step shown in FIGS. 1A and 2A:

FIG. 3A illustrating a supporting sheet and

FIG. 3B illustrating an assembly sheet.

FIG. 4 shows a laminated sheet of a second step of a second modified example.

### DESCRIPTION OF EMBODIMENTS

### 1. One Embodiment

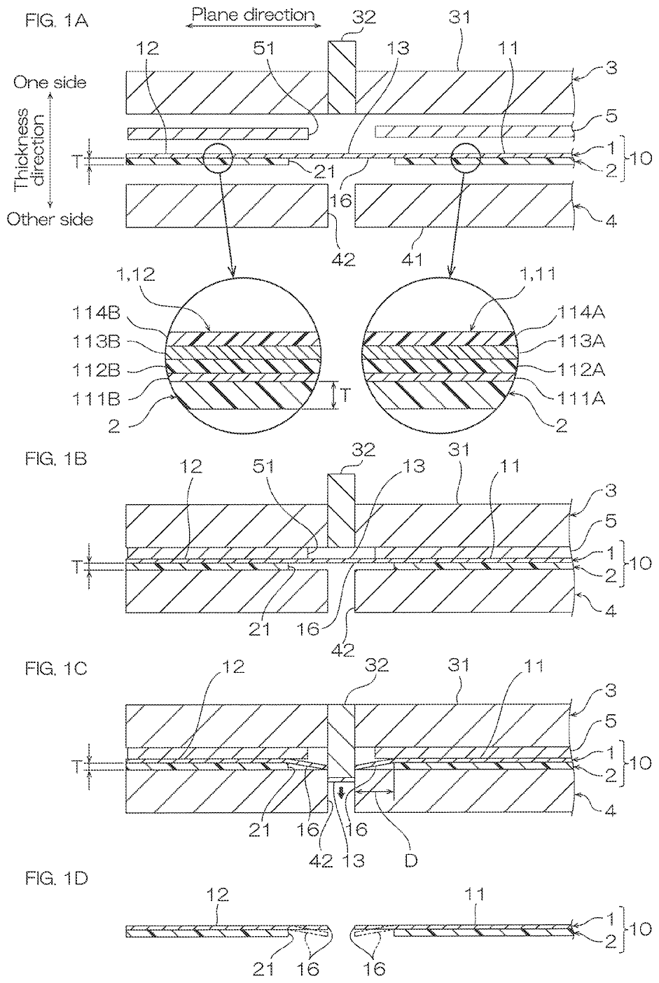

One embodiment of a method for producing a wiring circuit board of the present invention is described with reference to FIGS. 1A to 3B.

The method for producing a wiring circuit board includes a first step, a second step, and a third step in order. That is, in this producing method, the first step, the second step, and the third step are carried out in order.

### 1.1 First Step

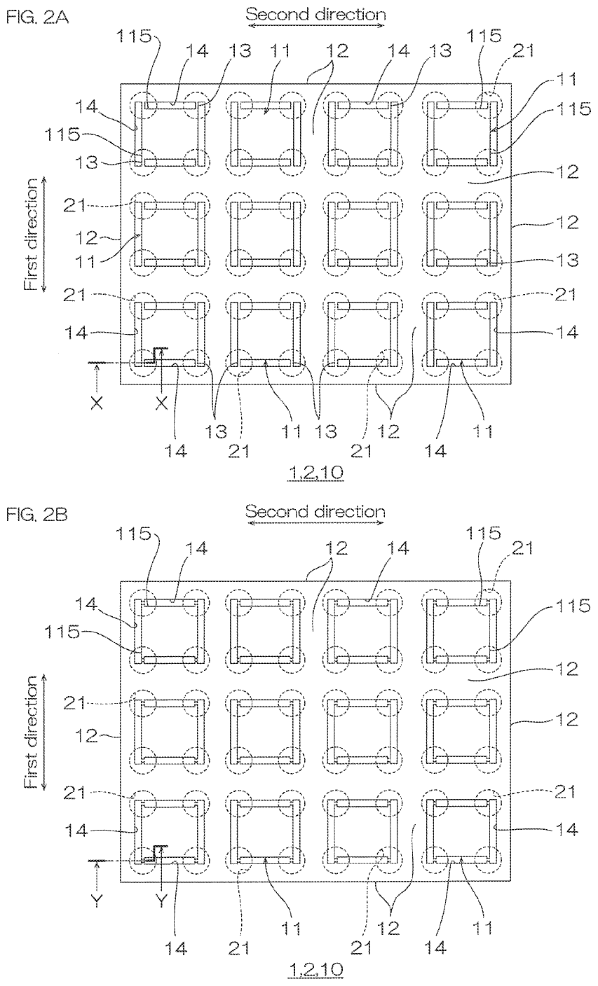

As shown in FIGS. 1B and 2A, in the first step, an assembly sheet 1 and a supporting sheet 2 are overlapped.

1.1.1 Assembly Sheet 1

As shown in FIGS. 1A and 1B, the assembly sheet 1 has a thickness. The “sheet” in the assembly sheet 1 is the same as a film. The sheets and the films are not distinguished. The assembly sheet 1 extends in a plane direction. The plane direction is perpendicular to a thickness direction. As shown in FIG. 2A, in the present embodiment, the assembly sheet 1 has a rectangular outer shape when viewed in the thickness direction. The assembly sheet 1 includes a plurality of wiring circuit boards 11, a supporting portion 12, and a joint 13. The assembly sheet 1 has a groove 14.

1.1.1.1 Plurality of Wiring Circuit Boards 11

The plurality of wiring circuit boards 11 are disposed inside a peripheral end portion in the assembly sheet 1. The plurality of wiring circuit boards 11 are disposed at spaced intervals from each other in the plane direction. In the present embodiment, the plurality of wiring circuit boards 11 are disposed in alignment each in a first direction and a second direction. The first direction and the second direction are included in the plane direction. The first direction and the second direction are perpendicular to each other. The first direction and the second direction are along the four rectangular sides of the assembly sheet 1.

As shown in FIG. 1A, each of the plurality of wiring circuit boards 11 is provided with a metal supporting layer 111A, an insulating layer 112A, a wiring layer 113A, and a cover insulating layer 114A toward one side in the thickness direction.

The metal supporting layer 111A is disposed in the other end portion of the wiring circuit board 11 in the thickness direction. The metal supporting layer 111A extends in the plane direction. Examples of a material for the metal supporting layer 111A include iron, stainless steel, copper, and copper alloy. A thickness of the metal supporting layer 111A is, for example, 1 μm or more, preferably 10 μm or more, and for example, 1000 μm or less, preferably 500 μm or less.

The insulating layer 112A is disposed on one surface of the metal supporting layer 111A in the thickness direction. The insulating layer 112A extends in the plane direction. In the present embodiment, the insulating layer 112A is a base insulating layer. An example of the material for the insulating layer 112A includes an insulating resin. An example of the insulating resin includes polyimide. The thickness of the insulating layer 112A is, for example, 1 μm or more, preferably 5 μm or more, and for example, 100 μm or less, preferably 50 μm or less.

The wiring layer 113A is disposed on one surface of the insulating layer 112A in the thickness direction. The wiring layer 113A extends in the plane direction. The wiring layer 113A has a pattern including a wiring and a terminal. Examples of the material for the wiring layer 113A include copper, silver, gold, iron, aluminum, chromium, and alloys of these. The thickness of the wiring layer 113A is, for example, 1 μm or more, preferably 3 μm or more, and for example, 50 μm or less, preferably 30 μm or less.

The cover insulating layer 114A is disposed in one end portion of the wiring circuit board 11 in the thickness direction. The cover insulating layer 114A is disposed on one surface of the insulating layer 112A in the thickness direction. Further, the cover insulating layer 114A covers the wiring of the wiring layer 113A. The cover insulating layer 114A extends in the plane direction. An example of the material for the cover insulating layer 114A includes an insulating resin. An example of the insulating resin includes polyimide. The thickness of the cover insulating layer 114A is, for example, 1 μm or more, preferably 5 μm or more, and for example, 100 μm or less, preferably 50 μm or less.

The thickness of the wiring circuit board 11 is, for example, 10 μm or more, preferably 25 μm or more, and for example, 1000 μm or less, preferably 500 μm or less. The thickness of the wiring circuit board 11 is the total thickness of the metal supporting layer 111A, the insulating layer 112A, the wiring layer 113A, and the cover insulating layer 114A.

1.1.1.2 Supporting Portion 12

As shown in FIG. 2A, the supporting portion 12 is disposed between the peripheral end portion in the assembly sheet 1 and the wiring circuit board 11 adjacent thereto in the plane direction. In the present embodiment, the supporting portion 12 has a generally lattice shape when viewed in the thickness direction.

The supporting portion 12 includes at least one layer (preferably, multiple layers) selected from the group consisting of a metal supporting layer 111B, an insulating layer 112B, a wiring layer 113B, and a cover insulating layer 114B.

The metal supporting layer 111B, the insulating layer 112B, the wiring layer 113B, and the cover insulating layer 114B are the same layer as the metal supporting layer 111A, the insulating layer 112A, the wiring layer 113A, and the cover insulating layer 114A described above. The supporting portion 12 preferably has the same layer configuration as the wiring circuit board 11. That is, the supporting portion 12 preferably includes the metal supporting layer 111B, the insulating layer 112B, the wiring layer 113B, and the cover insulating layer 114B. As shown in FIG. 1A, in the supporting portion 12, the metal supporting layer 111B, the insulating layer 112B, the wiring layer 113B, and the cover insulating layer 114B are disposed toward one side in the thickness direction.

The metal supporting layer 111B of the supporting portion 12 is the same layer as the metal supporting layer 111A of the wiring circuit board 11. The insulating layer 112B of the supporting portion 12 is the same layer as the insulating layer 112A of the wiring circuit board 11. The wiring layer 113B of the supporting portion 12 is the same layer as the wiring layer 113A of the wiring circuit board 11. The wiring layer 113B may be also configured not to send a signal and/or ground current. The cover insulating layer 114B of the supporting portion 12 is the same layer as the cover insulating layer 114A of the wiring circuit board 11.

The supporting portion 12 has the same thickness as the wiring circuit board 11. The assembly sheet 1 has the same thickness as the wiring circuit board 11 and the supporting portion 12. Specifically, the thickness of the assembly sheet 1 is, for example, 10 μm or more, preferably 25 μm or more, and for example, 1000 μm or less, preferably 500 μm or less.

1.1.1.3 Joint 13

As shown in FIG. 2A, the joint 13 connects the plurality of wiring circuit boards 11 to the supporting portion 12. The joint 13 traverses a groove 14 to be described next. The plurality of joints 13 are provided in the one wiring circuit board 11. In the present embodiment, the joint 13 is continuous to four corner portions 115 of the wiring circuit board 11.

The joint 13 includes at least one layer (preferably, multiple layers) selected from the group consisting of a metal supporting layer 111C, an insulating layer 112C, a wiring layer 113C, and a cover insulating layer 114C (not shown in FIG. 1A). The metal supporting layer 111C, the insulating layer 112C, the wiring layer 113C, and the cover insulating layer 114C are the same layers as the metal supporting layer 111A, the insulating layer 112A, the wiring layer 113A, and the cover insulating layer 114A described above. Preferably, the joint 13 includes only the metal supporting layer 111C.

1.1.1.4 Groove 14

The groove 14 is disposed around each of the plurality of wiring circuit boards 11. In the present embodiment, the groove 14 has a generally rectangular frame shape when viewed in the thickness direction. The groove 14 penetrates the assembly sheet 1 in the thickness direction. The groove 14 separates the wiring circuit board 11 from the supporting portion 12 in the plane direction. Further, the grooves 14 are divided into a plurality pieces by the joint 13 when viewed in the thickness direction. In the present embodiment, the grooves 14 are a plurality of slits.

1.1.2 Supporting Sheet 2

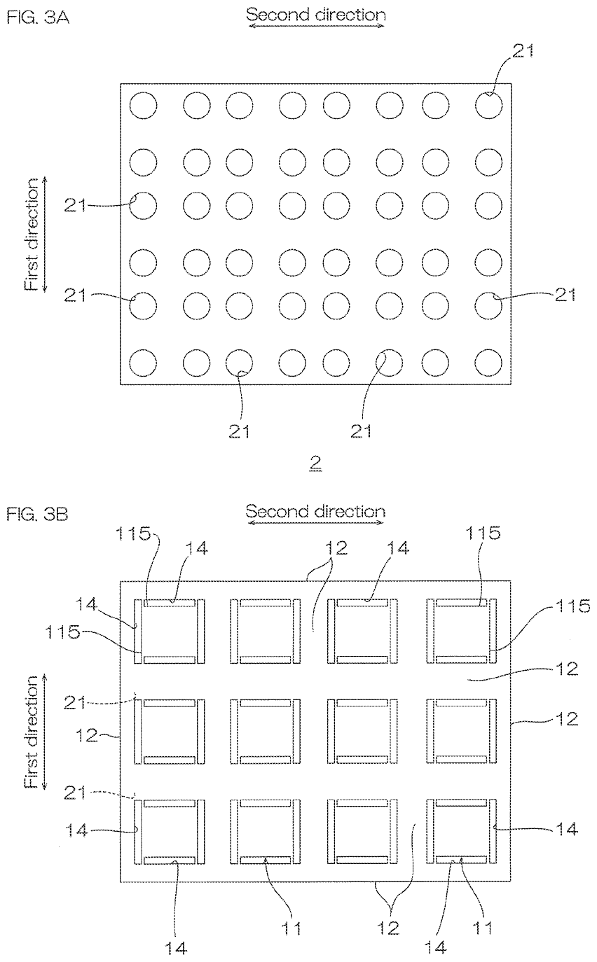

The supporting sheet 2 has a thickness. The supporting sheet 2 extends in the plane direction. In the present embodiment, as shown in FIG. 3A, the supporting sheet 2 has a rectangular outer shape when viewed in the thickness direction.

1.1.2.1 Material for Supporting Sheet 2

Examples of the supporting sheet 2 include resin sheets, metal sheets, and ceramic sheets, and from the viewpoint of transportability of the wiring circuit board 11, a resin sheet is used. Examples of a resin of the resin sheet include polyester films and polyolefin films, and preferably, from the viewpoint of improving strength, a polyester film is used. Examples of the polyester film include polyethylene terephthalate films (PET film), polyethylene naphthalate films, and polybutylene terephthalate films, and preferably, from the viewpoint of reducing cost, a PET film is used.

1.1.2.2 Dimension of Supporting Sheet 2

A thickness T of the supporting sheet 2 (ref: FIG. 1A) is, for example, 250 μm or less, preferably 150 μm or less, more preferably 75 μm or less, and for example, 10 μm or more, preferably 20 μm or more.

When the thickness T of the supporting sheet 2 is the above-described upper limit or less, in the second step to be described later, it is possible to suppress the deformation of a portion 16 (described later) facing an opening portion 21 in the assembly sheet 1.

1.1.2.3 Opening Portion 21

In the present embodiment, the supporting sheet 2 preferably has the opening portion 21. The opening portion 21 penetrates the supporting sheet 2 in the thickness direction. The plurality of opening portions 21 are disposed at intervals. As shown in FIGS. 1B and 2A, in the present embodiment, the opening portion 21 is disposed so as to face the joint 13 when the assembly sheet
is overlapped with the supporting sheet 2 in the thickness direction. The plurality of opening portions 21 are disposed so as to include (contain) the plurality of joints 13 when the assembly sheet 1 is overlapped with the supporting sheet 2 in the thickness direction. A dimension of the opening portion 21 is larger than that of the joint 13. In the present embodiment, the opening portion 21 has a circular shape when viewed in the thickness direction.

A total opening ratio of the plurality of opening portions 21 is, for example, 10% or more, preferably 20% or more, and for example, 50% or less, preferably 40% or less.

When the total opening ratio of the opening portion 21 is the above-described lower limit or more, in the second step to be described next, it is possible to suppress the deformation of the portion 16 facing the opening portion 21 in the assembly sheet 1. When the total opening ratio of the opening portion 21 is the above-described upper limit or less, in the third step, it is possible to suppress falling of the wiring circuit board 11 from the opening portion 21, and to improve the transportability of the wiring circuit board 11.

The total opening ratio of the plurality of opening portions 21 is a percentage of the area of the supporting sheet 2 when viewed in the thickness direction, and the total area of the plurality of opening portions 21 in the total area of the plurality of opening portions 21.

A ratio of the area of the joint 13 to the area of the opening portion 21 when overlapped in the thickness direction is, for example, 0.01 or more, preferably 0.015 or more, and for example, 0.3 or less.

In the first step, the assembly sheet 1 and the supporting sheet 2 are overlapped in the thickness direction. Specifically, in the first step, the above-described assembly sheet 1 and the supporting sheet 2 are overlapped in the thickness direction, thereby fabricating a laminated sheet 10. In the present embodiment, the laminated sheet 10 includes the supporting sheet 2 and the assembly sheet 1 in order toward one side in the thickness direction. That is, in the laminated sheet 10, the supporting sheet 2 and the assembly sheet 1 are disposed in order toward one side in the thickness direction. The assembly sheet 1 is disposed on one surface of the supporting sheet 2 in the thickness direction. The assembly sheet 1 is in contact with one surface of the supporting sheet 2 in the thickness direction.

The assembly sheet 1 is overlapped with the supporting sheet 2 so that the opening portion 21 includes the joint 13 when viewed in the thickness direction. At this time, the portion 16 facing the opening portion 21 in the assembly sheet 1 is exposed from the supporting sheet 2.

The one opening portion 21 corresponds to one corner portion 115.

In the first step, thereafter, the laminated sheet 10 is disposed between a first mold 3 and a second mold 4.

The first mold 3 has a first flat plate 31 and a punch 32. The first flat plate 31 has a thickness. The first flat plate 31 extends in the plane direction. The punch 32 extends along the thickness direction of the first flat plate 31. The punch 32 is capable of advancing and retracting toward the other side in the thickness direction (side of the second mold 4) with respect to the first flat plate 31. When the punch 32 advances and retracts, the punch 32 is guided by the first flat plate 31. A blade is provided in a front end portion (downstream-side end portion in an advancing direction) of the punch 32.

The plurality of punches 32 are provided corresponding to the plurality of joints 13. The first mold 3 is, for example, a metal mold.

The second mold 4 is disposed at intervals from the first mold 3 on the other side in the thickness direction thereof. The second mold 4 has a second flat plate 41 and a hole 42. The second flat plate 41 has a thickness. The second flat plate 41 extends in the plane direction. The second flat plate 41 is parallel to the first flat plate 31. The hole 42 penetrates the second flat plate 41 in the thickness direction. The plurality of holes 42 are provided corresponding to the plurality of punches 32. The hole 42 has a shape and dimension capable punching (cutting) the joint 13 when the punch 32 is inserted into the hole 42. The second mold 4 is, for example, a metal mold.

In the present embodiment, the laminated sheet 10 (the assembly sheet 1 and the supporting sheet 2) is disposed between the first mold 3 and the second mold 4 so that the assembly sheet 1 faces the first mold 3, and the supporting sheet 2 faces the second mold 4.

At this time, if necessary, a stripper plate 5 may be also disposed between the first flat plate 31 and the laminated sheet 10 (the assembly sheet 1). The stripper plate 5 has a second opening 51. The second opening 51 is overlapped with the opening portion 21 of the supporting sheet 2, the punch 32, and the hole 42 when viewed in the thickness direction. After cutting, when the punch 32 is pulled out of the hole 42, the stripper plate 5 is capable of peeling the punch 34 from the assembly sheet 1. The stripper plate 5 is, for example, a metal plate.

Then, the laminated sheet 10 and the stripper plate 5 are sandwiched between the first mold 3 and the second mold 4 in the thickness direction.

### 1.2 Second Step

As shown in FIGS. 1C and 2B, in the second step, the plurality of wiring circuit boards 11 are separated from the supporting portion 12 by cutting. Specifically, in the second step, the joint 13 is cut. To cut the joint 13, the punch 32 is inserted into the hole 42. Specifically, the joint 13 is pressed and cut, while the punch 32 is advanced from the first flat plate 31 toward the hole 42. Thus, the joint 13 is removed from the assembly sheet 1. Thus, the support for the wiring circuit board 11 by the supporting portion 12 is opened. Thus, the plurality of wiring circuit boards 11 are separated from the supporting portion 12.

Thereafter, though not shown, the punch 32 is pulled out of the hole 42.

### 1.3 Third Step

As shown in FIG. 1D, in the third step, the assembly sheet 1 including the plurality of wiring circuit boards 11 separated from the supporting portion 12 is conveyed, while being supported by the supporting sheet 2. In the conveyance of the assembly sheet 1, the above-described laminated sheet 10 including the assembly sheet 1 and the supporting sheet 2 is detached from the first mold 3 and the second mold 4, and the laminated sheet 10 is subjected to subsequent steps. The subsequent steps include an inspection step and a mounting step. In the inspection step, a presence or absence of deformation of the portion 16 is observed. When the subsequent steps are carried out, each of the plurality of wiring circuit boards 11 is pulled up from the supporting sheet 2. At this time, the support for the wiring circuit board 11 by the supporting sheet 2 is released.

Separately, the supporting sheet 2 is reused.

### 2. Function and Effect of One Embodiment

According to this producing method, as shown in FIG. 1D, since the plurality of wiring circuit boards 11 separated from the supporting portion 12 are conveyed, while being supported by the supporting sheet 2, the transportability of the plurality of wiring circuit boards 11 is excellent.

According to this producing method, as shown in FIGS. 1C and 2B, since in the second step, the joint 13 is cut, it is possible to reliably and easily separate the wiring circuit board 11 from the supporting portion 12.

Furthermore, since in the first step, the assembly sheet 1 is overlapped with the supporting sheet 2 so that the opening portion 21 of the supporting sheet 2 includes the joint 13 when viewed in the thickness direction. Therefore, in the second step, it is possible to suppress the contact of the punch 32 with the supporting sheet 2, and furthermore, to suppress the damage of the supporting sheet 2. Therefore, it is possible to suppress the occurrence of a foreign matter (dust generation) due to the above-described contact.

Further, since the damage of the supporting sheet 2 is suppressed, after the third step, it is possible to reuse the supporting sheet 2.

According to this producing method, when the supporting sheet 2 is the resin sheet, the handling of the supporting sheet 2 is simple, and the transportability of the plurality of wiring circuit boards 11 using the supporting sheet 2 is further more excellent.

When the total opening ratio of the plurality of opening portions 21 is below 20%, as shown in FIG. 1C, a distance D between an inner peripheral surface of the supporting sheet 2 defining the opening portion 21, and the hole 42 is shortened. Then, when the joint 13 is cut, large stress is applied to the portion 16 corresponding to the above-described inner peripheral surface as the portion 16 moves toward the hole 42, and the portion 16 is deformed toward the hole 42. Then, as shown by a virtual line in FIG. 1D, even when the punch 32 is pulled out of the hole 42, the above-described deformation may remain in the portion 16.

However, according to this producing method, when the total opening ratio of the plurality of opening portions 21 is 20% or more, it is possible to increase the distance D between the inner peripheral surface of the supporting sheet 2, and the hole 42, in the second step, to reduce the stress applied to the portion 16, and to suppress the deformation of the portion 16 facing the opening portion 21 in the assembly sheet 1.

Further, when the thickness T of the supporting sheet 2 is above 150 μm, as shown in FIG. 1C, an amount of movement of the portion 16 toward the hole 42 increases at the time of cutting of the joint 13. Therefore, the large stress is applied to the portion 16 corresponding to the above-described inner peripheral surface, and the portion 16 is deformed toward the hole 42. Then, as shown by the virtual line in FIG. 1D, even when the punch 32 is pulled out of the hole 42, the above-described deformation may remain in the portion 16.

However, according to this producing method, when the thickness T of the supporting sheet 2 is 150 μm or less, in the second step, it is possible to reduce the amount of movement of the portion 16 toward the hole 42, to reduce the stress applied to the portion 16, and to suppress the deformation of the portion 16 facing the opening portion 21 in the assembly sheet 1.

According to this producing method, as shown in FIG. 1B, in the first step, the assembly sheet 1 and the supporting sheet 2 are disposed between the first mold 3 and the second mold 4 so that the assembly sheet 1 faces the first mold 3 having the punch 32, and the supporting sheet 2 faces the second mold 4 having the hole. Thus, as shown in FIG. 1C, in the second step, it is possible to improve the position accuracy at the time of punching.

Further, in the second step, when the punch 32 is inserted into the hole 42, in the assembly sheet 1, the portion 16 in the outer vicinity of the punch 32 and facing the opening portion 21 is, as described above, moved toward the opening portion 21. Then, as shown in FIG. 1D, the assembly sheet 1 may be deformed due to the above-described movement of the portion 16 of the assembly sheet 1.

However, according to this producing method, as described above, when the total opening ratio of the plurality of opening portions 21 is 20% or more and/or the thickness T of the supporting sheet 2 is 150 μm or less, it is possible to effectively suppress the deformation of the portion 16.

### 3. Modified Examples

In each modified example below, the same reference numerals are provided for members and steps corresponding to each of those in the above-described one embodiment, and their detailed description is omitted. Further, each modified example can achieve the same function and effect as that of one embodiment unless otherwise specified. Furthermore, one embodiment and each modified example can be appropriately used in combination.

### 3.1 First Modified Example

In the first modified example, though not shown, the supporting sheet 2 does not have the opening portion 21.

Comparing the first modified example to one embodiment, one embodiment is preferable. In one embodiment, it is possible to suppress the contact of the punch 32 with the supporting sheet 2, and furthermore, to suppress the damage of the supporting sheet 2. Therefore, it is possible to suppress the occurrence of the foreign matter (dust generation) due to the above-described contact. Furthermore, since it is possible to suppress the damage of the supporting sheet 2, it is possible to reuse the supporting sheet 2.

### 3.2 Second Modified Example

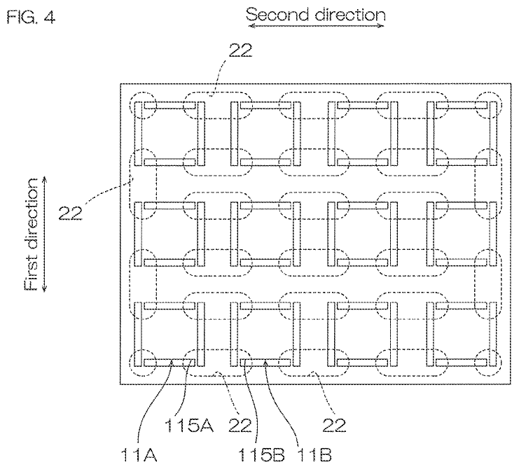

As shown in FIG. 4, one opening portion 22 may also correspond to two corner portions 115. The two corner portions 115 include a corner portion 115A in one wiring circuit board 11A, and a corner portion 115B in another wiring circuit board 11B adjacent to the one wiring circuit board 11A. The opening portion 22 has a long hole shape when viewed in the thickness direction. The assembly sheet 1 is overlapped with the supporting sheet 2 so that the above-described opening portion 22 includes the two corner portions 115A and 115B when viewed in the thickness direction.

### 3.3 Third Modified Example

In one embodiment, the first mold 3 is disposed at the upper side with respect to a fourth mold. However, though not shown, in the third modified example, the first mold 3 is disposed at the lower side with respect to the fourth mold.

### EXAMPLES

Next, the present invention is further described based on Examples below. The present invention is however not limited by these Examples. The specific numerical values in mixing ratio (content ratio), property value, and parameter used in the following description can be replaced with upper limit values (numerical values defined as “or less” or “below”) or lower limit values (numerical values defined as “or more” or “above”) of corresponding numerical values in mixing ratio (content ratio), property value, and parameter described in the above-described “DESCRIPTION OF EMBODIMENTS”.

### Example 1

[First Step]

Each of the assembly sheet 1 and the supporting sheet 2 was fabricated. The thickness of the assembly sheet 1 was 60 μm. The thickness of the metal supporting layers 111A, 111B, and 111C was 30 μm, and the material was copper alloy. The thickness of the insulating layers 112A, 112B, and 112C was 10 μm, and the material was polyimide. The thickness of the wiring layers 113A, 113B, and 113C was 10 μm, and the material was copper. The thickness of the cover insulating layers 114A, 114B, and 114C was 10 μm, and the material was polyimide.

The thickness T of the supporting sheet 2 was 25 μm. The supporting sheet 2 was a PET film. The opening portion 21 had a circular shape when viewed in the thickness direction. The total opening ratio of the plurality of opening portions 21 in the supporting sheet 2 was 13%.

As shown in FIGS. 1A and 2A, the assembly sheet 1 and the supporting sheet 2 were overlapped in the thickness direction, thereby fabricating the laminated sheet 10. The assembly sheet 1 and the supporting sheet 2 were overlapped so that the opening portion 21 included the joint 13 when viewed in the thickness direction. Thus, the laminated sheet 10 was fabricated.

The laminated sheet 10 was disposed between the first mold 3 and the second mold 4 so that the assembly sheet 1 faced the third mold 3, and the supporting sheet 2 faced the second mold 4. Subsequently, at the same time, the stripper plate 5 was disposed between the first flat plate 31 and the laminated sheet 10.

As shown in FIG. 1B, subsequently, the laminated sheet 10 and the stripper plate 5 were sandwiched between the first mold 3 and the second mold 4 in the thickness direction.

[Second Step]

As shown in FIGS. 1C and 2B, the punch 32 was inserted into the hole 42, and the joint 13 was cut, thereby separating the plurality of wiring circuit boards 11 from the supporting portion 12.

[Third Step]

As shown in FIG. 1D, the assembly sheet 1 including the plurality of wiring circuit boards 11 separated from the supporting portion 12 was conveyed, while being supported by the supporting sheet 2.

### Examples 2 to 10

The first step to the third step were carried out in the same manner as in Example 1. However, the thickness T of the supporting sheet 2 prepared in the first step, the diameter of the opening portion, and the total opening ratio were changed as described in Table 1.

[Evaluation]

Evaluation of Deformation

A deformation amount in the thickness direction in the portion 16 was measured. The deformation of the portion 16 was evaluated in accordance with the deformation amount as follows. The results are described in Table 1.
Excellent: deformation amount was below 30 μm.
Good: deformation amount was 30 μm or more and below 60 μm.
Fair: deformation amount was 60 μm or more.

[Table 1]

TABLE 1

| | | | Total Opening | |
|---|---|---|---|---|
| | Thickness of | Diameter of | Ratio of | |
| | Supporting | Opening | Opening | Deformation |
| | Sheet (μm) | Portion (μm) | Portion (%) | Amount |
| Ex. 1 | 25 | 3 | 13 | Good |
| Ex. 2 | 50 | 3 | 13 | Good |
| Ex. 3 | 100 | 3 | 13 | Good |
| Ex. 4 | 25 | 5 | 21 | Excellent |
| Ex. 5 | 50 | 5 | 21 | Excellent |
| Ex. 6 | 100 | 5 | 21 | Good |
| Ex. 7 | 25 | 8 | 43 | Excellent |
| Ex. 8 | 50 | 8 | 43 | Excellent |
| Ex. 9 | 100 | 8 | 43 | Good |
| Ex. 10 | 200 | 5 | 21 | Fair |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### DESCRIPTION OF REFERENCE NUMERALS

1 Assembly sheet
2 Supporting sheet
3 First mold
4 Second mold
11, 11A, 11B Wiring circuit board
12 Supporting portion
13 Joint
21, 22 Opening portion
32 Punch
42 Hole
111A, 111B, 111C Metal supporting layer
112A, 112B, 112C Insulating layer
113A, 113B, 113C Wiring layer

1. A method for producing a wiring circuit board comprising:
a first step of overlapping an assembly sheet including a plurality of wiring circuit boards and a supporting portion supporting the plurality of wiring circuit boards, and a supporting sheet for supporting the assembly sheet, in a thickness direction;
after the first step, a second step of separating the plurality of wiring circuit boards from the supporting portion by cutting; and
after the second step, a third step of conveying the assembly sheet including the plurality of wiring circuit boards separated from the supporting portion, while being supported by the supporting sheet.

2. The method for producing a wiring circuit board according to claim 1, wherein
the supporting sheet has an opening portion penetrating the thickness direction;
the assembly sheet includes a joint connecting the plurality of wiring circuit boards to the supporting portion;
in the first step, the assembly sheet is overlapped with the supporting sheet so that the opening portion includes the joint when viewed in the thickness direction; and
in the second step, the joint is cut.

3. The method for producing a wiring circuit board according to claim 1, wherein
the supporting sheet is a resin sheet.

4. The method for producing a wiring circuit board according to claim 2, wherein
the supporting sheet is a resin sheet.

5. The method for producing a wiring circuit board according to claim 1, wherein
both the wiring circuit board and the supporting portion include a metal supporting layer, an insulating layer, and a wiring layer in order toward one side in the thickness direction.

6. The method for producing a wiring circuit board according to claim 2, wherein
both the wiring circuit board and the supporting portion include a metal supporting layer, an insulating layer, and a wiring layer in order toward one side in the thickness direction.

7. The method for producing a wiring circuit board according to claim 1, wherein
a thickness of the assembly sheet is 500 μm or less.

8. The method for producing a wiring circuit board according to claim 2, wherein
a thickness of the assembly sheet is 500 μm or less.

9. The method for producing a wiring circuit board according to claim 2, wherein
the plurality of opening portions are disposed at intervals, and
a total opening ratio of the plurality of opening portions in the supporting sheet is 20% or more.

10. The method for producing a wiring circuit board according to claim 2, wherein
a thickness of the supporting sheet is 150 μm or less.

11. The method for producing a wiring circuit board according to claim 9, wherein
in the first step, the assembly sheet and the supporting sheet are disposed between a first mold having a punch, and a second mold disposed at intervals from the first mold in the thickness direction and having a hole so that the assembly sheet faces the first mold and the supporting sheet faces the second mold, and
in the second step, the joint is punched by inserting the punch into the hole.

12. The method for producing a wiring circuit board according to claim 10, wherein
in the first step, the assembly sheet and the supporting sheet are disposed between a first mold having a punch, and a second mold disposed at intervals from the first mold in the thickness direction and having a hole so that the assembly sheet faces the first mold and the supporting sheet faces the second mold, and
in the second step, the joint is punched by inserting the punch into the hole.
